(19) United States
(12) Patent Application Publication
(10) Pub. No.: US 2015/0081238 A1
(43) Pub. Date: Mar. 19, 2015

(54) RF Signal Meter

(71) Applicant: Purdue Research Foundation, West Lafayette, IN (US)

(72) Inventors: Abdullah Eroglu, West Lafayette, IN (US); Thomas Wolf, New Haven, IN (US); Brenton Weaver, Fort Wayne, IN (US); Evan Steinmetz, Fort Wayne, IN (US)

(73) Assignee: Purdue Research Foundation, West Lafayette, IN (US)

(21) Appl. No.: 14/470,000

(22) Filed: Aug. 27, 2014

Related U.S. Application Data
(60) Provisional application No. 61/870,351, filed on Aug. 27, 2013.

(51) Int. Cl. G01R 21/133; G01R 13/02; G01R 25/00

(52) U.S. Cl. CPC G01R 21/133; G01R 25/00; G01R 13/02
USPC 702/67

(57) ABSTRACT

A radio frequency (RF) meter configured to measure both scalar power and phase information is disclosed. The meter performs a calibration to account for properties of an external coupler connected to the meter inputs. Internal couplers are optionally provided which direct the input signals to a phase detector. The meter is optionally connected to a display and network connections for transmitting the scalar power and phase information.

### RELATED APPLICATIONS

The present application claims the benefit of U.S. provisional application Ser. No. 61/870,351, filed Aug. 27, 2013, the contents of which are hereby incorporated by reference in its entirety.

### FIELD OF THE INVENTION

The present application relates to measurement of radio-frequency signals, and to devices for carrying out such measurement.

### BACKGROUND OF THE INVENTION

Various meters, such as the Agilent, Model—V3500A Handheld RF Power Meter, measure radio-frequency (RF) power, but not phase. Many meters have a restricted range of input frequencies.

Current reflectometers need four coupled ports and are expensive and not off-the-shelf. Moreover, impedance measurement can be difficult to do at high power levels representative of actual operation using conventional reflectometers. Examples of conventional RF impedance analyzers include the MKS Instruments Model: VI-Probe-4100; and the MKS Model: VI-Probe-350.

Phase measurements are often performed using six RF ports, which can require complex RF setups. A Six port reflectometer can require eleven constants for its calibration. These coefficients are used to express the magnitude of the emerging wave, and the amplitude and complex ratio of the incoming and emerging waves, which can also be used to extract the phase and impedance information. However, the increasing number of standards for terminations, computational effort and the cost make six port reflectometers unattractive for phase or magnitude measurements.

Many conventional meters are calibrated only for specific external couplers and cannot be used with customers' existing couplers or with couplers better suited for the application than the specific coupler. There is, therefore, a need of a more flexible, less complex meter for RF power (or amplitude) and phase.

### BRIEF DESCRIPTION OF THE DRAWINGS

The above and other objects, features, and advantages of the present invention will become more apparent when taken in conjunction with the following description and drawings wherein identical reference numerals have been used, where possible, to designate identical features that are common to the figures, and wherein:

FIG. 1 shows a block diagram of a system according to one embodiment;

FIG. 2 is a high-level diagram showing the components of a data-processing system according to one embodiment; and

FIG. 3 shows simulated losses of a coupler according to one embodiment.

The attached drawings are for purposes of illustration and are not necessarily to scale.

### DETAILED DESCRIPTION OF THE INVENTION

In the following description, some aspects will be described in terms that would ordinarily be implemented as software programs. Those skilled in the art will readily recognize that the equivalent of such software can also be constructed in hardware, firmware, or micro-code. Because data-manipulation algorithms and systems are well known, the present description will be directed in particular to algorithms and systems forming part of, or cooperating more directly with, systems and methods described herein. Other aspects of such algorithms and systems, and hardware or software for producing and otherwise processing the signals involved therewith, not specifically shown or described herein, are selected from such systems, algorithms, components, and elements known in the art. Given the systems and methods as described herein, software not specifically shown, suggested, or described herein that is useful for implementation of any aspect is conventional and within the ordinary skill in such arts.

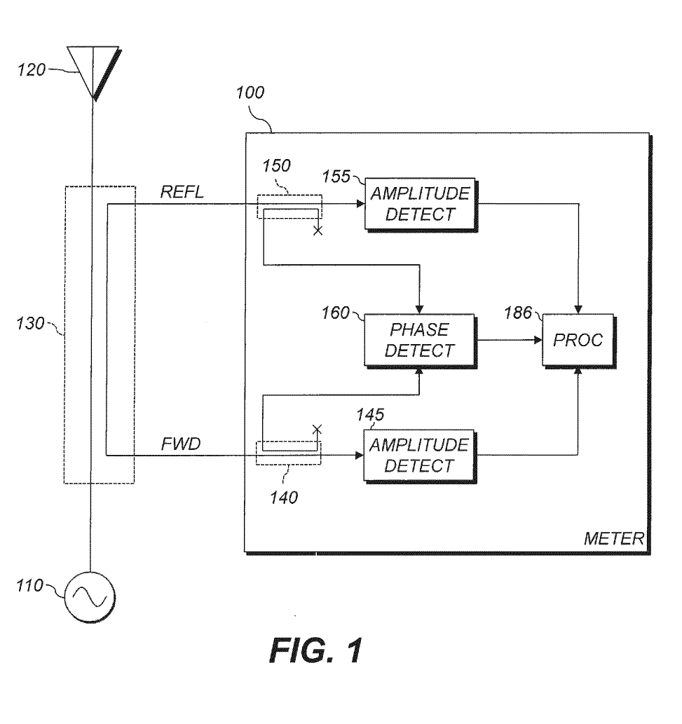

FIG. 1 shows a block diagram of a radio-frequency (RF) system, including a meter 100 and related components. RF source 110 provides a signal to antenna 120. Coupler 130 is a four-port coupler, e.g., supplied separately from the meter 100. A portion of the signal from source 110 passes along the “FWD” line and a portion of any reflections from antenna 120 passes along the “REFL” line. Meter 100 includes two more couplers 140 and 150. In one embodiment, the couplers 140 and 150 comprise microstrip directional couplers. The couplers 140, 150 provide advantages over resistive attenuators since the couplers provide improved bandwidth and low insertion-loss. This ensures that the scalar power measurements will not be adversely affected during calibration and measurement. The microstrip couplers 140,150 are preferably etched onto a printed circuit board contained within the meter 100 to act as a transmission line, which requires matching to reduce loss. The microstrip couplers 140, 150 optionally include mitered 90 degree bends to reduce the effect of the bends on the impedance of the transmission line.

The FWD and REFL signals have their amplitudes or powers measured by detection units 145, 155. The forward line from each coupler 140, 150 provides energy to phase detector 160. Units 145, 155, 160 provide data of measurements of the RF signal to processor 186. Processor 186 can perform error compensation and calibration processing, then provide magnitude, phase, or impedance- mismatch information.

Meter 100 can work with an external customer-supplied coupler, such as coupler 130. Prior meters are designed and calibrated to work only with a particular coupler. However, different RF signals can require different couplers, thereby limiting the usefulness of such coupler-specific meters. An external coupler has to meet the power requirements of the devices attached to it and be operative in the correct signal frequency range. In an example, meter 100 measures magnitude of signals between 1 MHz and 6 GHz and phase between 1 MHz and 2.7 GHz.

In one embodiment, detection units 145 and 155 each comprise a demodulating logarithmic amplifier, such as the ANALOG DEVICES Model 8318. The ANALOG DEVICES Model 8318 used to measure amplitude is described by ANALOG DEVICES thus: “As a measurement device, Pin VOUT is externally connected to VSET to produce an output voltage, V_{OUT}, which is a decreasing linear-in-dB function of the RF input signal amplitude.” Different measurement devices can be used for different frequency ranges. A segmentation approach can be used to determine how much error is present at a given frequency for a given meter 100 configuration.

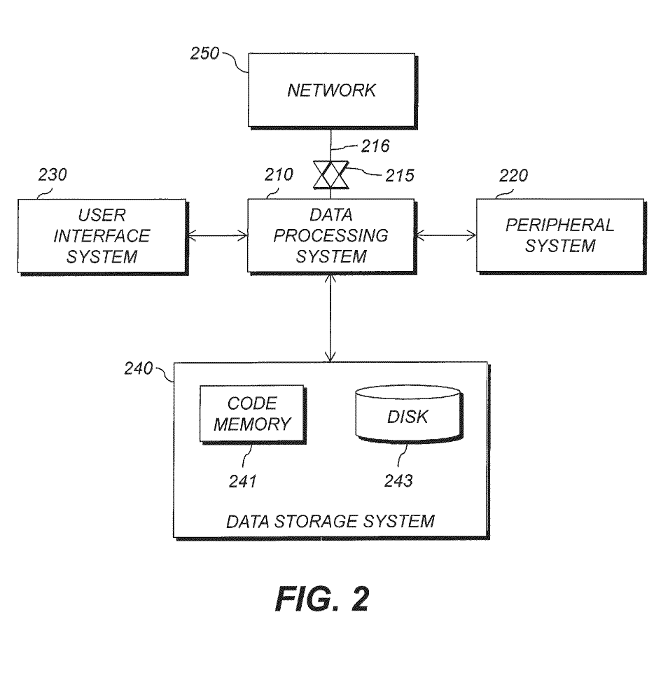

Meter 100 can be calibrated in the field for a particular coupler 130. This is done using a known source and known load. In various aspects, all calibration is algorithmic. The frequency of the known source can be provided to processor 186, e.g., via user interface system 230, FIG. 2, as can the dB rating of external coupler 130. Calibration loads can include 50 ohms, open, and short. The processor 186 can produce and later use calibration tables to compensate for error from external coupler 130 and internal couplers 140, 150. Separate look-up tables may be used for power and phase.

Phase calibration uses forward and reflected power. 0° and 180° reference signals can be measured into a known load. S-parameters can be measured and phase information derived from those and known configurations of the components, e.g., the reference-signal frequency and system characteristic impedance.

For power, calibration, attenuation levels can be measured, or attenuation curves provided by manufacturers can be used. These can be inverted to determine the coupler-input power level corresponding to a given coupler output.

Calibration parameters can be stored within meter 100 (e.g., in data storage system 240, FIG. 2) or on an external device such as a personal computer. Different sets of calibration parameters can be stored for different external couplers 130. The calibration can take into account the characteristics of couplers 130, 140, 150, and produce a single set of calibration data that will compensate for nonidealities in any of these, or other components of the signal path in coupler 130 or meter 100.

It has been observed that the directivity of the external coupler 130 is of particular importance in determining its measurement accuracy. In one embodiment, calibration of the external coupler 130 may be performed as described below.

The following is the general S-parameter equation for b₃ (reflected wave at port 3) in a directional 4-port coupler with the source at port 1, forward-coupled line at port 3, reverse-coupled line at port 2, and the load at port 4:

b₃=s₃₁a₁+s₃₂a₂+s₃₃a₃+s₃₄a₄ (1)

b₃=s₃₁a₁+s₃₂Γ₂s₂₁a₁+s₃₄Γ₄b₄+s₃₂Γ₂s₂₄Γ₄b₄+s₃₃a₃ (2)

b₃=s₃₁a₁+s₃₂Γ₂(s₂₁a₁+s₂₄Γ₄b₄)+s₃₃a₃+s₃₄Γ₄b₄ (3)

where:
bᵢ=the reflected wave at port i.
aᵢ=the incident wave at port i.
Γᵢ=the reflection coefficient for port i.
s₃₁a₁—Forward coupled power from P1 to P3: very large compared to other signals.
S₃₂Γ₂—This is multiplied by all power terms incident to P2 to give the contribution of this power to that incident to P3.
s₂₁a₁—Power emergent from port 1 multiplied by s₂₁ gives power incident to P2 resulting from a₁.
s₂₄Γ₄b₄—Note that Γ₄b₄=a₄, this is the power reflected from the DUT. So multiplied by s₂₄ gives the power incident to P2 resulting from a₄.
s₃₃a₃—This is the power incident to P3 resulting from reflected power at P3. With matched detector this is close to zero.
s₃₄Γ₄b₄—Power at P3 resulting from a₄=Γ₄b₄=reflected power from the load/DUT. In a good directional coupler (high directivity) this is very small.

Several properties of the directional coupler 130 can simplify the above equations. For highly matched detectors, a₃=a₂≈0. Also, loose coupling gives b₄≈a₁=\sqrt{P₁} since only a small amount of power is coupled. Finally, the coupler is also assumed to be a low-loss device, which gives |s₃₂|=|s₄₁|≈1. Also, the coupling factor is K_{c}=|s₂₄|⁻²=|s₃₁|⁻² and the directivity is related to the s-parameters as √K_{d}K_{c}=|s₂₁|⁻¹=|s₃₄|⁻¹. These simplifications give:

$$\begin{matrix}{b}_{3} = {s}_{31} {a}_{1} + 0 + 0 + {s}_{34} {Γ}_{4} {b}_{4} & ( 4 ) \\ {b}_{3} = \frac{\sqrt{{P}_{1}}}{\sqrt{{K}_{c}}} {∠θ}_{1} + \frac{1}{\sqrt{{K}_{d} {K}_{c}}} \vert {Γ}_{4} \vert \sqrt{{P}_{1}} {∠θ}_{4} & ( 5 ) \\ {b}_{3} = \sqrt{\frac{{P}_{1}}{{K}_{c}}} [ 1 {∠θ}_{1} + \frac{\vert {Γ}_{4} \vert}{\sqrt{{K}_{d}}} {∠θ}_{4} ] & ( 6 )\end{matrix}$$

The power at port 3 is then given by squaring the magnitude of b₃, which takes on a minimum and maximum value due to the two phases. The maximum is given when θ₁=θ₄ when the magnitudes are added, and the minimum occurs when the two components are 180 degrees out of phase per equation (7) below.

$${P}_{3} = {\frac{{P}_{1}}{{K}_{c}} [ 1 \pm \frac{\vert {Γ}_{4} \vert}{\sqrt{{K}_{d}}} ]}^{2} \qquad ( 7 )$$

Similarly, the power at port 2 is found by using the s-parameter equation for b₂ with the same simplifications:

$$\begin{matrix}{b}_{2} = {s}_{21} {a}_{1} + {s}_{22} {a}_{2} + {s}_{23} {a}_{3} + {s}_{24} {a}_{4} & ( 8 ) \\ {b}_{2} = {s}_{21} {a}_{1} + 0 + 0 + {s}_{24} {Γ}_{4} {b}_{4} & ( 9 ) \\ {b}_{2} = \frac{\sqrt{{P}_{1}}}{\sqrt{{K}_{d} {K}_{c}}} {∠θ}_{1} + \frac{\vert {Γ}_{4} \vert}{\sqrt{{K}_{d}}} \sqrt{{P}_{1}} {∠θ}_{4} & ( 10 ) \\ {b}_{2} = \frac{\sqrt{{P}_{1}}}{\sqrt{{K}_{c}}} [ \frac{1}{\sqrt{{K}_{d}}} {∠θ}_{1} + \vert {Γ}_{4} \vert {∠θ}_{4} ] & ( 11 ) \\ {P}_{2} = {\frac{{P}_{1}}{{K}_{c}} [ \vert {Γ}_{4} \vert \pm \frac{1}{\sqrt{{K}_{d}}} ]}^{2} & ( 12 )\end{matrix}$$

In a reflectometer measurement, the reflected power reading is divided by the forward power reading, and the resulting fraction is square-rooted to give the reflection coefficient magnitude. This gives the equation:

$$\vert {Γ}_{4 , measured} \vert = \sqrt{\frac{{P}_{2}}{{P}_{3}}} = \frac{\vert {Γ}_{4} \vert \pm \frac{1}{\sqrt{{K}_{d}}}}{1 \pm \frac{\vert {Γ}_{4} \vert}{\sqrt{{K}_{d}}}} \qquad ( 13 )$$

Which can be made clearer by pulling out a |Γ₄| term from the numerator:

$$\vert {Γ}_{4 , measured} \vert = \vert {Γ}_{4} \vert [ \frac{1 \pm \frac{1}{\vert {Γ}_{4} \vert \sqrt{{K}_{d}}}}{1 \pm \frac{\vert {Γ}_{4} \vert}{\sqrt{{K}_{d}}}} ] \qquad ( 14 )$$

Equation (14) demonstrates how the directivity and the magnitude of the return loss (−20 log₁₀|Γ₄|) can adversely affect the measurement accuracy of the reflection coefficient of the DUT (device under test). It is also shows that the forward measurement gains accuracy as return loss decreases, while the reverse measurement loses accuracy as return loss decreases. Higher coupler directivity increases accuracy in all cases.

It is also important to note that both the coupling factor and the input power level have no influence on the measurement of the reflection coefficient magnitude. Therefore, these parameters may be adjusted to meet the requirements of the detectors 145, 155 without affecting the measurement accuracy. In a preferred embodiment, the detectors 145, 155 are closely matched to a 50 ohm system. The forward and reflected power measurements may require a further calibration to correct for the external coupler 130 and the power being supplied by the system generator.

In one embodiment, the processor calculates the value of

$$\frac{{P}_{1}}{\sqrt{{K}_{c}}} .$$

With a constant-power generator this will be a constant value, and will allow the correction of both the forward and reverse measurements due to the coupling of the external coupler 130.

In one embodiment, the calibration of the external coupler 130 will take place as a separate stage from the calibration of the detectors 145, 155. This separation simplifies the calibration of the external coupler 130, since only one power level from the generator is needed to characterize the coupling coefficient.

FIG. 2 is a high-level diagram showing the components of a data-processing system for analyzing data and performing other analyses described herein. The system includes a data processing system 210, a peripheral system 220, a user interface system 230, and a data storage system 240. The peripheral system 220, the user interface system 230 and the data storage system 240 are communicatively connected to the data processing system 210. Processor 186 can include one or more of systems 210, 220, 230, 240.

The data processing system 210 includes one or more data processing devices that implement the processes of the various aspects, including the example processes described herein. The phrases “data processing device” or “data processor” are intended to include any data processing device, such as a central processing unit (“CPU”), a desktop computer, a laptop computer, a mainframe computer, a personal digital assistant, a Blackberry™, a digital camera, cellular phone, or any other device for processing data, managing data, or handling data, whether implemented with electrical, magnetic, optical, biological components, or otherwise.

The data storage system 240 includes one or more processor-accessible memories configured to store information, including the information needed to execute the processes of the various aspects, including the example processes described herein. The data storage system 240 can be a distributed processor-accessible memory system including multiple processor-accessible memories communicatively connected to the data processing system 210 via a plurality of computers or devices. On the other hand, the data storage system 240 need not be a distributed processor-accessible memory system and, consequently, can include one or more processor-accessible memories located within a single data processor or device.

The phrase “processor-accessible memory” is intended to include any processor-accessible data storage device, whether volatile or nonvolatile, electronic, magnetic, optical, or otherwise, including but not limited to, registers, floppy disks, hard disks, Compact Discs, DVDs, flash memories, ROMs, and RAMs.

The phrase “communicatively connected” is intended to include any type of connection, whether wired or wireless, between devices, data processors, or programs in which data can be communicated. The phrase “communicatively connected” is intended to include a connection between devices or programs within a single data processor, a connection between devices or programs located in different data processors, and a connection between devices not located in data processors. In this regard, although the data storage system 240 is shown separately from the data processing system 210, one skilled in the art will appreciate that the data storage system 240 can be stored completely or partially within the data processing system 210. Further in this regard, although the peripheral system 220 and the user interface system 230 are shown separately from the data processing system 210, one skilled in the art will appreciate that one or both of such systems can be stored completely or partially within the data processing system 210.

The peripheral system 220 can include one or more devices configured to provide digital content records to the data processing system 210. For example, the peripheral system 220 can include digital still cameras, digital video cameras, cellular phones, or other data processors. The data processing system 210, upon receipt of digital content records from a device in the peripheral system 220, can store such digital content records in the data storage system 240.

The user interface system 230 can include a mouse, a keyboard, another computer, or any device or combination of devices from which data is input to the data processing system 210. In this regard, although the peripheral system 220 is shown separately from the user interface system 230, the peripheral system 220 can be included as part of the user interface system 230.

The user interface system 230 also can include a display device, a processor-accessible memory, or any device or combination of devices to which data is output by the data processing system 210. In this regard, if the user interface system 230 includes a processor-accessible memory, such memory can be part of the data storage system 240 even though the user interface system 230 and the data storage system 240 are shown separately in FIG. 9.

In view of the foregoing, aspects of the invention provide improved magnitude and phase measurement. A technical effect is to convert an RF signal to power and phase, and to determine impedance mismatch of source 110 and an RF load such as antenna 120. Processor 186, described above, can include a data processing system 210 and one or more of systems 220, 230, or 240.

As will be appreciated by one skilled in the art, aspects of the present invention may be embodied as a system, method, or computer program product. Accordingly, aspects of the present invention may take the form of an entirely hardware aspect, an entirely software aspect (including firmware, resident software, micro-code, etc.), or an aspect combining software and hardware aspects that may all generally be referred to herein as a “service,” “circuit,” “circuitry,” “module,” and/or “system.” Furthermore, aspects of the present invention may take the form of a computer program product embodied in one or more computer readable medium(s) having computer readable program code embodied thereon.

A computer program product can include one or more storage media, for example; magnetic storage media such as magnetic disk (such as a floppy disk) or magnetic tape; optical storage media such as optical disk, optical tape, or machine readable bar code; solid-state electronic storage devices such as random access memory (RAM), or read-only memory (ROM); or any other physical device or media employed to store a computer program having instructions for controlling one or more computers to practice method(s) according to various aspects(s).

Any combination of one or more computer readable medium(s) may be utilized. The computer readable medium may be a computer readable signal medium or a computer readable storage medium. A computer readable storage mediwn may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Program code and/or executable instructions embodied on a computer readable medium may be transmitted using any appropriate medium, including but not limited to wireless, wireline, optical fiber cable, RF, or any suitable combination of appropriate media.

Computer program code for carrying out operations for aspects of the present invention may be written in any combination of one or more programming languages. The program code may execute entirely on the user's computer (device), partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). The user's computer or the remote computer can be non- portable computers, such as conventional desktop personal computers (PCs), or can be portable computers such as tablets, cellular telephones, smartphones, or laptops.

Computer program instructions can be stored in a computer readable medium that can direct a computer, other programmable data processing apparatus, or other devices to function in a particular manner. The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified herein.

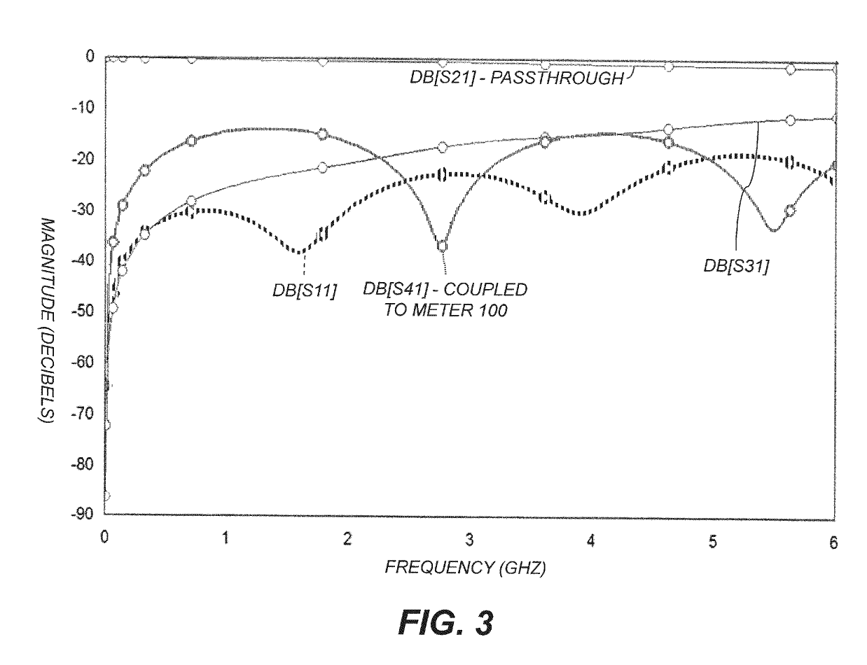

FIG. 3 shows simulated results of a coupler such as coupler 140, 150. The S41 trace shows the amount of RF energy coupled from the input (from coupler 130) to the phase detector 160.

The invention is inclusive of combinations of the aspects described herein. References to “a particular aspect” and the like refer to features that are present in at least one aspect of the invention. Separate references to “an aspect” or “particular aspects” or the like do not necessarily refer to the same aspect or aspects; however, such aspects are not mutually exclusive, unless so indicated or as are readily apparent to one of skill in the art. The use of singular or plural in referring to “method” or “methods” and the like is not limiting. The word “or” is used in this disclosure in a non-exclusive sense, unless otherwise explicitly noted.

The invention has been described in detail with particular reference to certain preferred aspects thereof, but it will be understood that variations, combinations, and modifications can be effected by a person of ordinary skill in the art within the spirit and scope of the invention.

What is claimed:

1. A radio-frequency (RF) meter, comprising:
a) a forward-signal input and a reflected-signal input;
b) respective couplers attached to the inputs;
c) respective power detectors attached to the respective couplers;
d) a phase detector attached to both of the respective couplers; and
e) a processor connected to the power detectors and the phase detectors.

2. The meter according to claim 1, wherein the processor is adapted to determine an impedance mismatch using data from the power detectors and the phase detectors.

3. The meter according to claim 1, wherein the processor is adapted to perform a calibration to account for properties of an external coupler attached to the inputs.

4. The meter according to claim 1, wherein said respective couplers comprise microstrip couplers.

5. The meter according to claim 4, wherein a first port of the microstrip coupler is connected to the phase detector and a second port of the microstrip coupler is connected to a ground via a resistor.

6. The meter according to claim 1, wherein the meter is configured to connect to a four-port external coupler.

7. The meter according to claim 6, wherein said respective couplers comprise microstrip couplers.

8. The meter according to claim 1, wherein the processor is further configured to transmit phase and amplitude information to a display.

9. The meter according to claim 8, wherein the processor is adapted to perform a calibration prior to transmitting said phase and amplitude information to the display, the calibration accounting for properties of an external coupler attached to the inputs.

10. A method of measuring an RF signal, comprising:
a) receiving from an RF source the RF signal in a coupler connected to the RF source and an RF load;
b) transmitting a portion of the received RF signal and a portion of a reflected signal received from the RF load to an RF meter;
c) receiving the portions in respective couplers in the RF meter;
d) automatically determining respective amplitudes of the signals using amplitude detectors connected to the respective couplers in the RF meter; and
e) automatically determining a phase of the RF signal using a phase detector connected to the respective couplers in the RF meter.

11. The method according to claim 10, further comprising: transmitting said respective amplitudes and phase to an external display.

12. The method according to claim 10, wherein a processor operatively connected to the meter is adapted to determine an impedance mismatch using data from the power detectors and the phase detectors.

13. The method according to claim 10, wherein the processor is adapted to perform a calibration to account for properties of an external coupler attached to the inputs.

14. The meter according to claim 10, wherein said respective couplers comprise microstrip couplers.

15. The method according to claim 14, wherein a first port of the microstrip coupler is connected to the phase detector and a second port of the microstrip coupler is connected to a ground via a resistor.

16. The method according to claim 10, wherein the meter is configured to connect to a four-port external coupler.

17. The method according to claim 16, wherein said respective couplers comprise microstrip couplers.

18. The method according to claim 11, wherein the processor is further configured to transmit phase and amplitude information to the display over a network, wherein the display is located remotely from the meter.

19. The method according to claim 18, wherein the processor is adapted to perform a calibration prior to transmitting said phase and amplitude information to the display, the calibration accounting for properties of an external coupler attached to the inputs.

20. The method according to claim 19, wherein the calibration includes determining a directivity of the external coupler.
